(19) United States
(12) Patent Application Publication
(10) Pub. No.: US 2010/0155937 A1
(43) Pub. Date: Jun. 24, 2010

(54) Wafer structure with conductive bumps and fabrication method thereof

(76) Inventors: Hung-Hsin Hsu, Hsinchu (TW); Chin-Ming Hsu, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/318,311

(22) Filed: Dec. 24, 2008

(51) Int. Cl. H01L 23/48; H01L 21/44

(52) U.S. Cl. 257/737; 438/613; 257/E21.159; 257/E23.169

(57) ABSTRACT

A wafer structure with conductive bumps and fabrication method thereof are disclosed herein. Conductive bumps are later converted into conductive balls. A central area and a marginal area are defined on the wafer. To achieve heights among conductive balls formed on the wafer structure, the sizes (can be but not limited to one) of under bump metallurgy (UBM) layer blocks in the central area are smaller than that in the marginal area. The fabrication procedure for forming under bump metallurgy layer blocks of different size includes depositing a photoresist layer on the metallurgy layer and pattern the photoresist with a photomask of smaller opening area for the central area than for the marginal area, and removing the photoresist layer and the portion of metallurgy layer under the photoresist layer.

### BACKGROUND OF THE INVENTION

1. Field of the Invention

The present invention relates to a semiconductor component with conductive bumps and its fabrication method, applied particularly to flip chip and wafer level chip size package.

2. Description of the Related Art

Owing to the progression of semiconductor fabrication technology, the ever increasing functionalities of chip circuits, and the accompanying large growth in demand for portable communication, internet and computer products, shrinkable integrated circuit area with high density and high lead count semiconductor package technology such as ball grid array and flip chip has become the main stream.

When it comes to flip chip semiconductor package technology, conductive bumps are formed on bump pads of semiconductor-based materials such as a wafer or a chip, and directly connected with a substrate, for example, electrically. Compared to the traditional wire bonding technology, flip chip technology has shorter circuit paths and better electrical properties, and since the back of a die is designed to be exposed, the heat of a chip can be better dissipated. Based on aforementioned reasons, flip chip technology are widely applied in the semiconductor packaging industry.

Presently, forming conductive bumps by electroplating requires plating a conductive thin film and conductive bumps on a wafer, and heating the conductive bumps to a temperature above their melting point. As a result of the cohesion effect, conductive bumps should become metal balls of even height. However, due to the current distribution effect of electroplating, heights of metal balls in the central area of a wafer are lower than those in the marginal area, resulting in unevenness of metal balls. Current products utilizing wafer level chip size package (WLCSP) need to undergo a grinding procedure after the metal balls are formed to reduce the thickness of a wafer, and then proceed with the post fabrication procedures such as dicing and packaging. During the grinding procedure, there must be grinding tapes attached to metal balls, and if heights of metal balls on the surface of a wafer are uneven, it can lead to extra stress, produced by grinding tapes, accumulating at the bottom of metal balls, causing danger in breaking chips and low reliability of the finished products.

### SUMMARY OF THE INVENTION

In order to solve aforementioned problem, one objective of the present invention is to provide a semiconductor component with conductive bumps and its fabrication method, which adjusts the heights of the conductive balls by modifying the sizes of the metal layer blocks under the conductive bumps. By achieving more even heights for conductive balls, the reliability of the finished products is improved, and stress built up at the bottom of the conductive balls and the probability of breaking a wafer are reduced.

In order to solve aforementioned problem, one embodiment of the present invention discloses a wafer structure with conductive bumps including a wafer with a plurality of bond pads arranged on the active surface of the wafer, wherein a central area and a marginal area are defined on the wafer; an insulation layer deposited on the wafer, and a plurality of openings formed on the insulation layer to expose each of the bond pads; a metal layer cut into a plurality of under bump metallurgy (UBM) layer blocks, each covering lateral and bottom surfaces of one of the openings, wherein sizes of the under bump metallurgy (UBM) layer blocks located at the central area are smaller than that at the marginal area; and a plurality of conductive bumps formed on the under bump metallurgy (UBM) layer blocks.

One embodiment of the present invention is a fabrication method of a wafer structure with conductive bumps, of which steps includes providing a wafer containing a plurality of bond pads arranged on its active surface, and a central area and a marginal area are defined on the wafer; depositing an insulation layer on the wafer and creating a plurality of openings on the insulation layer to expose each of the bond pads; depositing a metal layer on the insulation layer wherein the metal layer covers the openings; depositing a photoresist layer on the metal layer and create a plurality of patterned openings on the photoresist layer via photomasking to expose a portion of the metal layer on the bond pads, wherein sizes of the patterned openings in the central area of the wafer are relatively smaller than that in the marginal area; forming a plurality of conductive bumps on the portion of the metal layer exposed by the patterned openings; and removing the photoresist layer and the portion of metal layer under the photoresist layer.

Below, the embodiments are described in detail in cooperation with the attached drawings to make easily understood the objectives, technical contents, characteristics and accomplishments of the present invention.

### BRIEF DESCRIPTION OF THE DRAWINGS

The objectives, technical contents and characteristics of the present invention can be more fully understood by reading the following detailed description of the preferred embodiments, with reference made to the accompanying drawings, wherein:

FIG. 1A-FIG. 1H are diagrams showing the cross-sectional view of the fabrication procedures for the wafer structure with conductive bumps; and

FIG. 1I is a zoomed-in diagram of a portion of FIG. 1H.

### DETAILED DESCRIPTION OF THE INVENTION

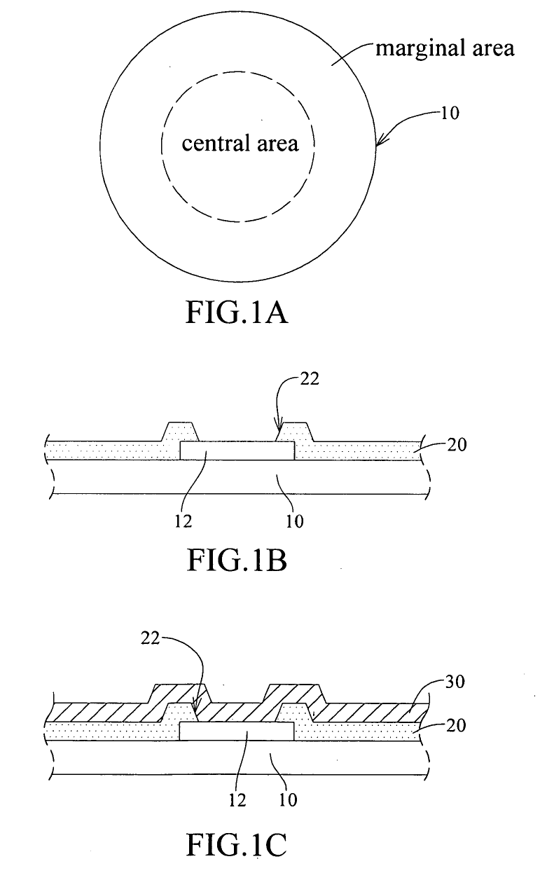

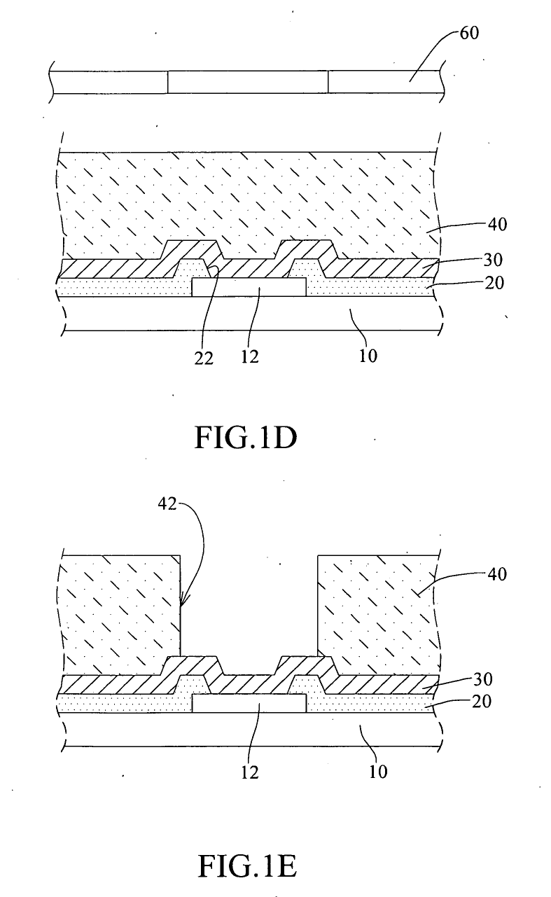

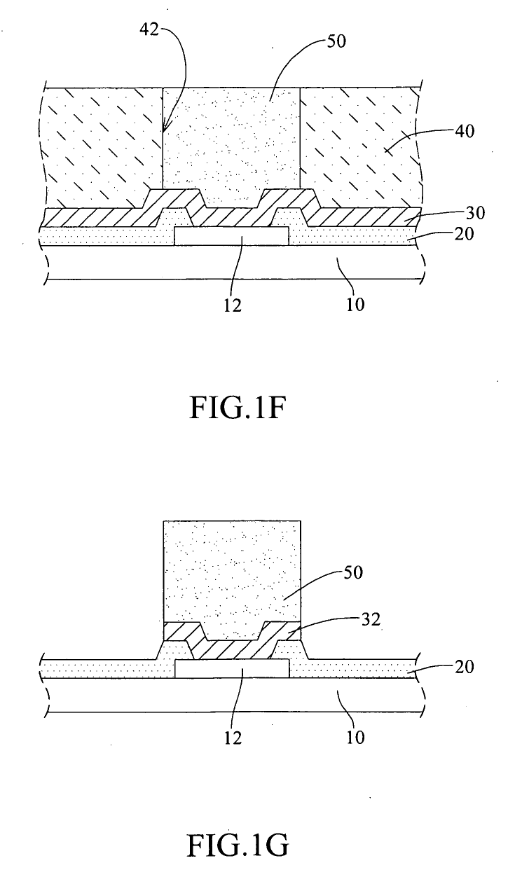

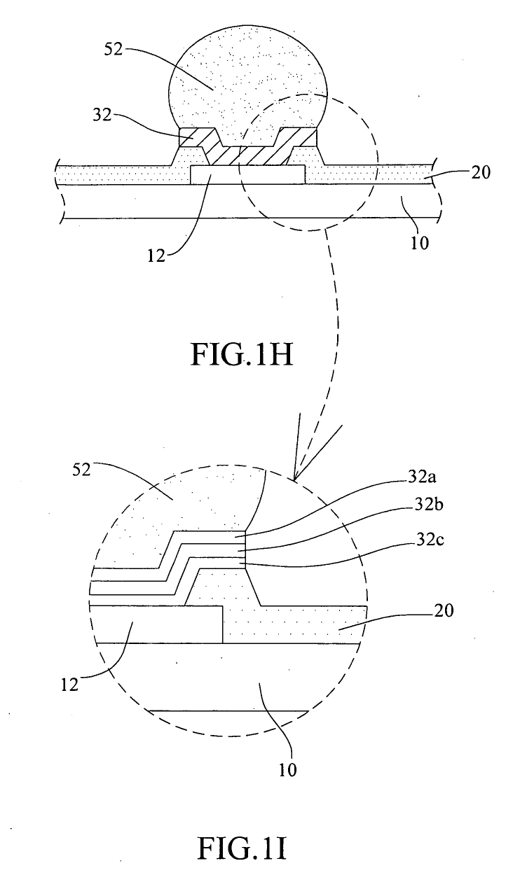

Please referring to FIG. 1A, FIG. 1B, FIG. 1C, FIG. 1D, FIG. 1E, FIG. 1F, FIG. 1G and FIG. 1H, they constitute a flowchart of the fabrication method for a wafer structure with conductive bumps disclosed by the present invention. First, as shown in FIG. 1A, a wafer 10 is provided, wherein the wafer 10 contains a plurality of bond pads (not shown in the figure) arranged on the active surface of the wafer 10, and a central area and a marginal area are defined on the wafer 10. Then, FIG. 1B shows the cross-sectional view of a wafer structure with bond pads 12 where only one bond pad is shown in the figure. As shown in FIG. 1B, an insulation layer 20 is deposited on the wafer 10, and a plurality of the openings 22 are created to expose each bond pad 12. In one embodiment, the size of openings 22 is slightly smaller than the size of bond pads 12. Next, please referring to FIG. 1C, a metal layer 30 is deposited on the insulation layer 20, covering openings 22 of the insulation layer 20. In one embodiment, methods for depositing metal layer 30 include sputtering and electrolyte less plating. Then, please referring to FIG. 1D and FIG. 1E, a photoresist layer 40 is deposited on the metal layer 30, and a photomask 60 is used to pattern the photoresist layer 40. In one embodiment, patterned openings 42 are created on the photoresist 40 to expose a portion of metal layer 30 located above the bond pads 12, as shown in FIG. 1E. In the present embodiment, the sizes (can be but not limited to one) of the patterned openings located at the central area of wafer 10 are relatively smaller than that at the marginal area.

In continuation of the aforementioned description, please referring to FIG. 1F, the patterned openings 42 of the photoresist 40 are filled solidly with conductive materials to form conductive bumps 50 on the metal layer 30 exposed by the patterned openings 42. Furthermore, as shown in FIG. 1G, conductive bump 50 structures are formed by etching away the photoresist layer 40 and the metal layer 30 covered by the photoresist layer 40. In one embodiment, the fabrication method further includes a solder reflow step, which converts conductive bumps 50 into conductive balls 52, as shown in FIG. 1H. The present invention adjusts the heights of conductive balls 52 by modifying the sizes of the metal layer blocks thereunder via changing the size of the patterned openings on the photomask. By achieving even heights for conductive balls, stress built up at the bottom of the conductive balls and the probability of breaking the wafer 10 is reduced.

In continuation to the above description, please referring to FIG. 1G, one embodiment of the present invention discloses a wafer structure with conductive bumps including a wafer 10 with a plurality of bond pads 12 arranged on the active surface of the wafer 10, wherein the a central area and a marginal area are defined on the wafer 10. An insulation layer 20 is deposited on the wafer 10, and a plurality of openings are created on the insulation layer 20 to expose each bond pad 12. After the photoresist layer 40 covering the metal layer 30 is removed (please refer to both FIG. 1F and FIG. 1G), the metal layer 30 is patterned, forming under bump metallurgy (UBM) layer blocks 32, which cover the lateral and bottom surfaces of openings 12, wherein the sizes (can be but not limited to one) of the under bump metallurgy (UBM) layer blocks 32 located in the central area are slightly smaller than that at the marginal area. And a plurality of conductive bumps 50 are formed on the under bump metallurgy (UBM) layer blocks 32.

Moreover, in one embodiment, as shown in FIG. 1I, where FIG. 1I is a diagram showing a zoomed-in portion of FIG. 1H, each under bump metallurgy (UBM) layer block 32 includes a bump connecting layer 32a, a barrier layer 32b and a circuit connecting layer 32c. The bump connecting layer 32a connects with one of conductive bumps 50; the circuit connecting layer 32c contacts with one of bond pads 12 and a portion of the insulation layer 20; and the barrier layer 32b is interposed between the bump connecting layer 32a and the circuit connecting layer 32c. In another embodiment, the insulation layer 20 further includes a Benzo-Cyclo-Butene (BCB) layer.

In conclusion, the present invention proposes a semiconductor component with conductive bumps and its fabrication method. By modifying the sizes of the under bump metallurgy (UBM) layer blocks, the heights of conductive balls can be adjusted. Besides, by achieving more even heights for conductive balls, the reliability of the finished products is improved and stress built up at the bottom of conductive balls and the probability of breaking a wafer are reduced.

The embodiments described above are to demonstrate the technical contents and characteristics of the present invention to enable the persons skilled in the art to understand, make, and use the present invention. However, it is not intended to limit the scope of the present invention. Therefore, any equivalent modification or variation according to the spirit of the present invention is to be also included within the scope of the present invention.

What is claimed is:

1. A wafer structure with conductive bumps comprising:
a wafer with a plurality of bond pads arranged on the active surface of said wafer, wherein a central area and a marginal area are defined on said wafer;
an insulation layer deposited on said wafer, and a plurality of openings formed on said insulation layer to expose each of said bond pads;
a metal layer cut into a plurality of under bump metallurgy (UBM) layer blocks, each covering lateral and bottom surfaces of one of said openings, wherein sizes of said under bump metallurgy layer blocks located at said central area are smaller than that at said marginal area; and
a plurality of conductive bumps formed on said under bump metallurgy layer blocks.

2. The wafer structure with conductive bumps according to claim 1, wherein each of said under bump metallurgy layer blocks comprises a bump connecting layer, a barrier layer, and a circuit connecting layer.

3. The wafer structure with conductive bumps according to claim 2, wherein each said bump connecting layer connects with one of said conductive bumps, each said circuit connecting layer contacts with one of said bond pads and a portion of said insulation layer, and said barrier layer is interposed between said bump connecting layer and said circuit connecting layer.

4. The wafer structure with conductive bumps according to claim 1, wherein said insulation layer further comprises a Benzo-Cyclo-Butene (BCB) layer.

5. A fabrication method for a wafer structure with conductive bumps of which steps comprise:
providing a wafer containing a plurality of bond pads arranged on its active surface, and a central area and a marginal area are defined on said wafer;
depositing an insulation layer on said wafer and creating a plurality of openings on said insulation layer to expose each of said bond pads;
depositing a metal layer on said insulation layer wherein said metallurgy layer covers said openings;
depositing a photoresist layer on said metal layer and create a plurality of patterned openings on said photoresist layer via photomasking to expose a portion of said metal layer on said bond pads, wherein sizes of said patterned openings in said central area of said wafer are relatively smaller than that in said marginal area;
forming a plurality of conductive bumps on the portion of said metal layer exposed by said patterned openings; and
removing said photoresist layer and the portion of metal layer under said photoresist layer.

6. The fabrication method for a wafer structure with conductive bumps according to claim 5 further comprising a solder reflow step which converts said conductive bumps into a ball shape.

7. The fabrication method for a wafer structure with conductive bumps according to claim 5, wherein method for depositing said metal layer can be sputtering or electrolyte less plating.

8. The fabrication method for a wafer structure with conductive bumps according to claim 5, wherein method for forming said conductive bumps can be sputtering or electroplating.
